(19) United States
(12) Patent Application Publication
(10) Pub. No.: US 2016/0351524 A1
(43) Pub. Date: Dec. 1, 2016

(54) INTEGRATED CIRCUIT

(71) Applicant: Novatek Microelectronics Corp., Hsinchu (TW)

(72) Inventors: Yu-Chang Pai, Hsinchu County (TW); Chien-Hsi Lee, Miaoli County (TW)

(21) Appl. No.: 14/727,842

(22) Filed: Jun. 1, 2015

(51) Int. Cl. H01L 23/00

(52) U.S. Cl. CPC H01L 24/48; H01L 24/05

(57) ABSTRACT

An integrated circuit is provided. The integrated circuit includes first pads and second pads. The first pads are used to receive a first type signal, and the second pads are used to receive a second type signal which is different from the first type signal. The first and second pads are alternately disposed on the integrated circuit, and form pad rows. Each of the pad rows has a part of the first pads and a part of the second pads. Each of the first pads directly neighbors with a plurality of neighboring pads of the second pads.

### BACKGROUND

Field of the Invention

The invention is directed to an integrated circuit and more particularly, to a mechanism of arranging pads of the integrated circuit.

Description of Related Art

With the advancement of electronic technologies, people's demands for information have been significantly increased. Accordingly, it is essential for electronic products to provide data transmission in a great amount and at a high speed.

With respect to data transmission and storage, a memory integrated circuit having a parallel interface with a high pin count is provided to provide a capability of massively and rapidly transmitting data. Accordingly, the memory integrated circuit needs a great number of pads disposed thereon, and under the consideration of minimizing a chip area, a plurality of pas in the integrated circuit which are used to transmit a data signal may be arranged together intensively and even two or more pads for transmitting the data signal are arranged adjacent to one another. Therefore, when the data signal are transmitted among the pads arranged adjacent to one another, interference may occur to the data signal transmitted on neighboring bonding wires due to a coupling effect between the bonding wires. Specially, in a high-speed transmission interface, transmission efficiency of the data signal may be affected due to the interference.

### SUMMARY

The invention provides an integrated circuit capable of effectively reducing mutual interference resulted from data signal sending and receiving.

The invention is directed to an integrated circuit including a plurality of first pads and a plurality of second pads. The first pads are sued to receive a first type signal, and the second pads are sued to receive a second type signal which is different from the first type signal. The first pads and the second pads are alternately disposed on the integrated circuit and form a plurality of pad rows. Each of the pad rows has a part of the first pads and a part of the second pads, each of the first pads directly neighbors with a plurality of neighboring pads of the second pads.

In an embodiment of the invention, the first type signal is a data signal whose voltage value varies with time, and the second type signal is a power signal.

In an embodiment of the invention, the second type signal includes a power voltage and a reference ground voltage.

In an embodiment of the invention, the first pads respectively receive a plurality of bits of a data signal.

In an embodiment of the invention, each of the first and second pads in each of the pad rows is not aligned with each of the first and second pads in each of the neighboring pad rows.

In an embodiment of the invention, the first and the second pads are connected with one or more external circuits through bonding wires.

In an embodiment of the invention, the pad rows are formed on a side of the integrated circuit.

In an embodiment of the invention, wherein each of the first pads are surrounded by the neighboring second pads.

To sum up, in the integrated circuit of the invention, the first pads and the second pads respectively used to receive different types of signal are alternately disposed on the integrated circuit, and the neighboring pads neighboring with the first pads are all second pads. Namely, each of second pads is provided between each two first pads no matter which direction each two first pads are in to achieve an isolation effect. Thereby, the mutual interference occurring to the data signal between each of the first pads can be effectively shielded to elevate transmission efficiency of the data signal.

In order to make the aforementioned and other features and advantages of the invention more comprehensible, several embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic diagram illustrating an integrated circuit according to an embodiment of the invention.

FIG. 2 is a schematic illustrating a scenario of bonding wires of the first and the second pads according to an embodiment of the invention.

FIG. 3 is a schematic diagram illustrating an integrated circuit according to an embodiment of the invention.

FIG. 4 illustrates one implementation of a layout of the first and the second pads according to an embodiment of the invention.

### DESCRIPTION OF EMBODIMENTS

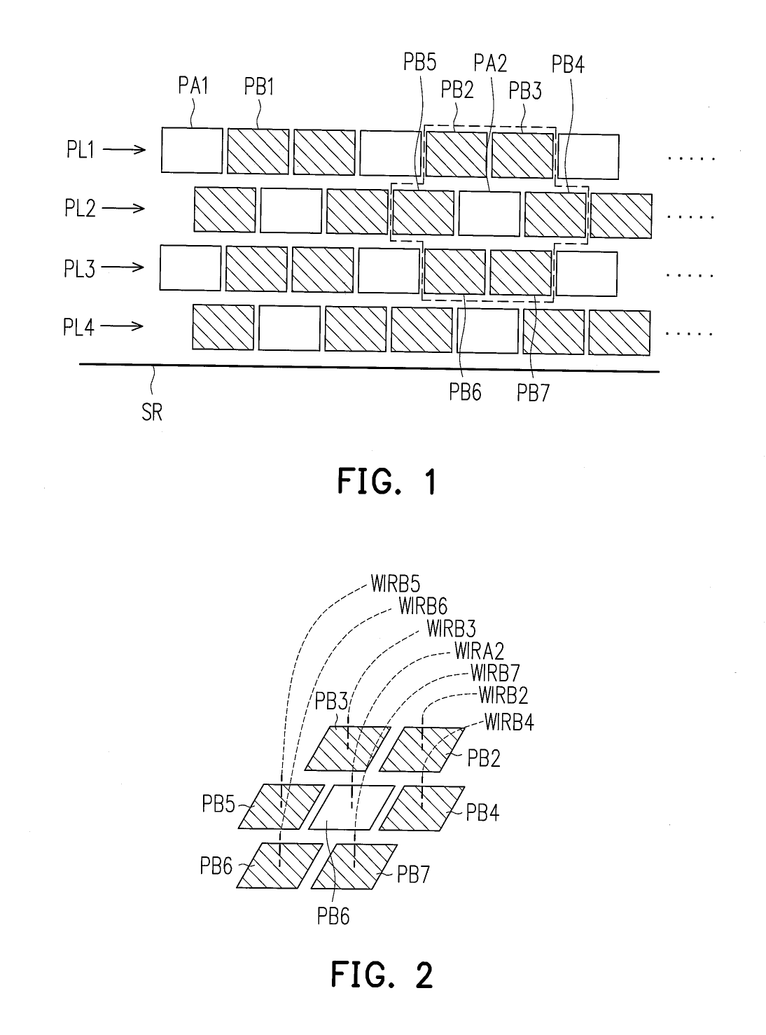

Referring to FIG. 1, FIG. 1 is a schematic diagram illustrating an integrated circuit according to an embodiment of the invention. An integrated circuit 100 includes a plurality of first pads PA1 and PA2 and a plurality of second pads PB1 to PB7. The first pads PA1 and PA2 and the second pads PB1 to PB7 are alternately disposed on the integrated circuit 100. In the present embodiment, the first pads PA1 and PA2 and the second pads PB1 to PB7 are divided into four pad rows PL1 to PL4. Each of the pad rows PL1 to PL4 includes a plurality of first pads and a plurality of second pads, and the pad rows PL1 to PL4 are laid out near a chip edge SR of the integrated circuit 100. Additionally, each of the first and second pads in each of the pad rows PL1 to PL4 is not aligned with each of the first and second pads in each of the neighboring pad rows to present a quincunx-type configuration manner.

It should be noted that in the present embodiment, the first pads PA1 and PA2 are used to receive a first type signal, and the second pads PB1 to PB7 are used to receive a second type signal. To be specific, the first type signal may be a signal whose voltage value varies with time, e.g., a data signal, while the second type signal may be a power signal whose voltage value does not vary with time, e.g., a power voltage or a reference ground voltage signal. The first type signal received by all the first pads may be integrated as a complete data signal. That is, each of the first pads receives each bit of the data signal. Since the data signal may change rapidly, the data signal whose each bit received by each of the first pads may be a signal whose state is rapidly transferred along with time between a high level (a high logic level) and a low level (a low logic level).

It should be further noted that in the present embodiment, a plurality of neighboring pads neighboring with each of the first pads are the second pads used to receive the second type signal. Taking a layout area AR1 for example, there are five neighboring pads directly neighboring with the first pads PA2, and the five neighboring pads are the second pads PB2 to PB7 used to receive the second type signal. Further, the first pads PA2 is surrounded by the second pads PB2 to PB7.

Additionally, the second pads PB2 to PB7 does not have to receive the same signal. A part of the second pads PB2 to PB7 may receive a power voltage (e.g., a highest voltage received by the integrated circuit 100), and another part of the second pads PB2 to PB7 may receive a reference ground voltage (e.g., a 0-V voltage). Certainly, the voltage value of the second type signal is not limited to one of the highest voltage or the 0-V voltage, and the voltage value of the second type signal may also be an arbitrary voltage with a voltage value between the highest level and 0 V.

Referring to FIG. 2, FIG. 2 is a schematic illustrating a scenario of bonding wires of the first and the second pads according to an embodiment of the invention. Herein, the second pads PB2 to PB7 are respectively connected with bonding wires WIRB2 to WIRB7 and connected with external circuits through the bonding wires WIRB2 to WIRB7. The first pads PA1 is connected with a bonding wire WIRA2 and connected with an external circuit through the bonding wire WIRA2. According to the illustration of FIG. 2, the bonding wire WIRA2 is surrounded by the bonding wires WIRB2 to WIRB7, and thus, the bonding wire WIRA2, no matter which direction it is in, is isolated from other bonding wires for transmitting the first type signal by at least one of the bonding wires WIRB2 to WIRB7. Namely, the signal transmitted on the bonding wire WIRA2 is neither interfered by other first type signals transmitted on another bonding wires nor interferes the transmission of the first type signals on other bonding wires.

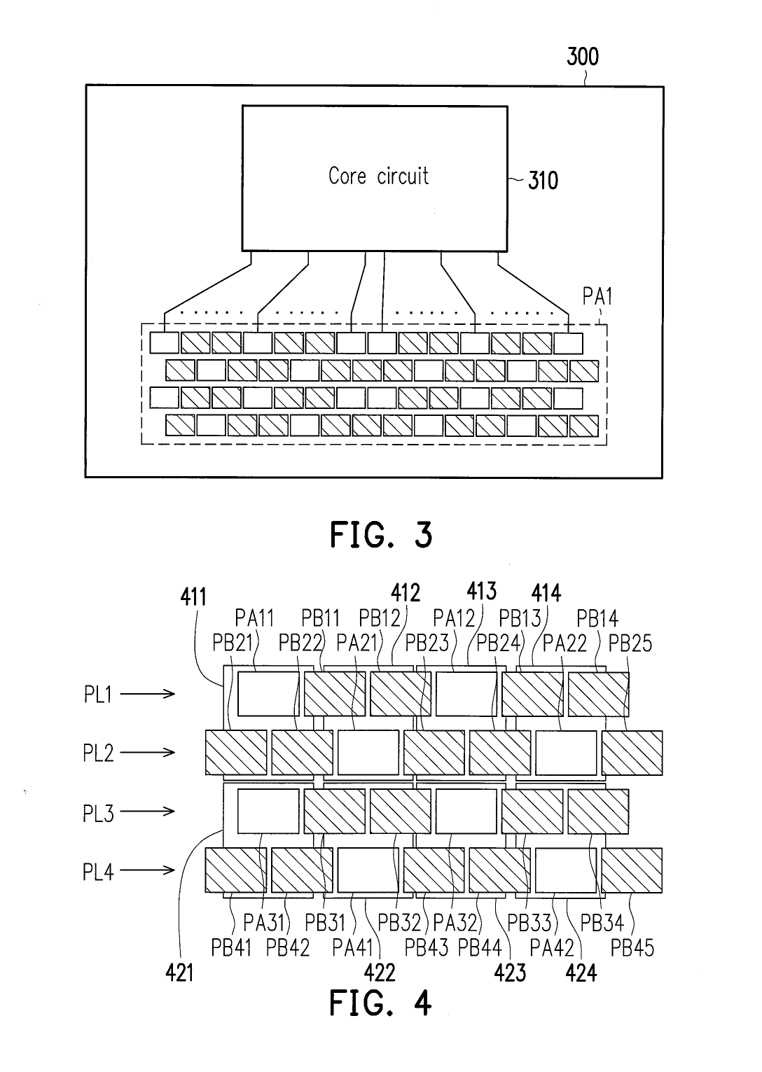

Referring to FIG. 3, FIG. 3 is a schematic diagram illustrating an integrated circuit according to an embodiment of the invention. An integrated circuit 300 includes a pad region PR1 and a core circuit 310. A plurality of first pads and a plurality of second pads depicted in FIG. 1 are disposed in the pad region PR1. The core circuit 310 is coupled with the first and the second pads in the pad region PR1. The pad region PR1 is laid out at a side of the integrated circuit 300, and the core circuit 310 may be laid out on a central position of the integrated circuit 300.

In the present embodiment, in order to avoid the layout of the pads in the pad region PR1 from becoming a pad limit to the chip size, and the first and the second pads in the pad region PR1 may be arranged as a plurality of pad rows according to a shape and a size of the layout of the core circuit 310. In the embodiment illustrated in FIG. 3, the pad region PR1 has four pad rows. Certainly, the number of the pad rows is not limited to four and may be configured based on a precondition that the layout area of the integrated circuit 300 can be minimized to the smallest.

Referring to FIG. 4, FIG. 4 illustrates one implementation of a layout of the first and the second pads according to an embodiment of the invention. The integrated circuit of FIG. 4 includes a plurality of input/output (I/O) stage circuits 411 to 414 and 421 to 424. The I/O stage circuits 411 to 414 and 421 to 424 are respectively arranged in two rows, and the I/O stage circuits 411 to 414 are laid out in the first row, and the I/O stage circuits 421 to 424 are arranged in the second row. The I/O stage circuits 411 and 413 correspond to first pads PA11 and PA12, respectively, the first pads PA11 and PA12 cover the I/O stage circuits 411 and 413, and the first pads PA11 and PA12 and second pads PB11 to PB14 are disposed on a first pad row PL1. Besides, the I/O stage circuits 412 and 414 correspond to first pads PA21 and PA22, the first pads PA21 and PA22 cover the I/O stage circuits 412 and 414, and the first pads PA21 and PA22 and second pads PB21 to PB25 are disposed on a second pad row PL2.

The I/O stage circuits 421 and 423 correspond to first pads PA31 and PA32, respectively, the first pads PA31 and PA32 cover the I/O stage circuits 421 and 423, and the first pads PA31 and PA32 and second pads PB31 to PB34 are disposed on a third pad row PL3. Besides, the I/O stage circuits 422 and 424 correspond to first pads PA41 and PA42, the first pads PA41 and PA42 cover the I/O stage circuits 422 and 424, and the first pads PA41 and PA42 and second pads PB41 to PB45 are disposed on a fourth pad row PL4.

It should be noted that through the aforementioned manner, the first pads PA11 to PA42 and the second pads PB11 to PB45 are alternately disposed on the I/O stage circuits 411 to 424, such that in a condition that no additionally chip area is occupied, each pad which directly neighbors with the first pads PA11 to PA42 is the second pad used to transmit the second type signal. In this way, the transmission of the first type signal on the first pads PA11 to PA42 can be prevented from being interfered, and the data signal can be accurately and rapidly transmitted.

To conclude, in the invention, all the neighboring pads directly neighboring with first pads are the pads for receiving the second type signal, and the second type signal can contribute to achieving an isolation effect for each of the first pads. Thereby, the mutual interference occurring during the first type signal being transmitted and the received can be mitigated, and the reliability of high-speed transmission of the data signal may maintained to enhance overall efficiency of the integrated circuit.

Although the invention has been described with reference to the above embodiments, it will be apparent to one of the ordinary skill in the art that modifications to the described embodiment may be made without departing from the spirit of the invention. Accordingly, the scope of the invention will be defined by the attached claims not by the above detailed descriptions.

1. An integrated circuit, comprising:
a plurality of first pads, used to receive a first type signal; and
a plurality of second pads, used to receive a second type signal which is different from the first type signal,
wherein the first pads and the second pads are alternately disposed on the integrated circuit and form a plurality of pad rows, each of the pad rows has a part of the first pads and a part of the second pads, each of the first pads merely directly neighbors with a plurality of neighboring pads of the second pads, and any two of the first pads are not directly neighbored to each other.

2. The integrated circuit according to claim 1, wherein the first type signal is a data signal whose voltage value varies with time, and the second type signal is a power signal.

3. The integrated circuit according to claim 2, wherein the second type signal comprises a power voltage and a reference ground voltage.

4. The integrated circuit according to claim 1, wherein the first pads respectively receive a plurality of bits of a data signal.

5. The integrated circuit according to claim 1, each of the first and second pads in each of the pad rows is not aligned with each of the first and second pads in each of the neighboring pad rows.

6. The integrated circuit according to claim 1, wherein the first and the second pads are connected with one or more external circuits through bonding wires.

7. The integrated circuit according to claim 1, wherein the pad rows are formed on a side of the integrated circuit.

8. The integrated circuit according to claim 1, wherein each of the first pads are surrounded by the neighboring second pads.
